(19) United States
(12) Patent Application Publication
(10) Pub. No.: US 2021/0178427 A1
(43) Pub. Date: Jun. 17, 2021

(54) PROCESS FOR THE PRODUCTION OF A MULTILAYER MATTE COATED SURFACE AND A PRODUCT CONTAINING A MULTILAYER COATED SURFACE

(71) Applicant: SCHATTDECOR SP. Z.O.O., Tarnowo Podgorne (PL)

(72) Inventors: Jerzy SZEJWIAN, Tarnowo Podgórne (PL); Krzysztof KONIECZNY, Tarnowo Podgórne (PL); Mateusz NOWAK, Tarnowo Podgórne (PL); Micha&#322; SMUS, Tarnowo Podgórne (PL)

(21) Appl. No.: 17/257,310

(22) PCT Filed: Jul. 1, 2019
(86) PCT No.: PCT/PL2019/000050

§ 371 Date: Dec. 31, 2020

(30) Foreign Application Priority Data
Jul. 2, 2018 (PL) P.426181

(51) Int. Cl. B05D 5/02; C09D 7/65; B05D 7/00; B05D 3/06

(52) U.S. Cl. CPC B05D 5/02; C09D 7/65; B05D 7/586; B05D 3/067; B05D 3/068; B05D 7/546

(57) ABSTRACT

Invention concerning a method for the production of a multilayer matte coated surface, where the carrier (1) is covered with a layer of coating (4) containing an additive to increase the bond strength of the coating between the layers. The coating layer is exposed to excimer radiation with a wavelength of 172 nm and afterwards treated with an electron beam with the dose required to achieve the gelatinisation of the coating, or with UV radiation in order to obtain an adequate gelatinisation effect. A least one other layer of coating with bond strength improving additive is applied to the first layer, which is again exposed to excimer radiation and an electron beam or UV radiation with the same dose as for the first layer. if the second layer is the outer layer, i.e. the last layer (6), the entire surface is treated with an electron beam with the dose required to finish the polymerisation process of all coating layers, or is treated with appropriate UV radiation, in order to achieve an adequate hardening effect.

The invention concerns also a furniture product containing a multilayer matte coated surface obtained with the method according to the invention.

The subject-matter of the invention is a method for the production of a multilayer matte coated surface and a product containing a multilayer matte coated surface on carriers like paper foils or plastic carriers, in particular BOPP, CPP and PVC.

The invention can be applied for the production of furniture surfaces. It can also be used to provide structure in the production of melamine surfaces.

Decorative coated materials used on furniture surfaces are paper or plastic foils, unprinted or printed by means of intaglio, flexographic or digital printing, etc., covered with colourless or colour coating.

Known are concave three-dimensional coated surfaces, whose structure is printed for example by means of a special paint with anti-adhesive properties and convex surfaces, in which the overprint of the structure is obtained with paint with extenders or varnish. Another division divides surfaces into synchronous surfaces, in which the three-dimensional structure reflects the elements of the print pattern, and asynchronous, in which the three-dimensional structure does not reflect the print pattern.

For practical reasons and in view of the aesthetic preferences of the consumers, furniture manufacturers use boards with a matte finish for the furniture production. The currently known technologies allow to obtain a matte finish on coated surfaces by using coatings, both water-based and EB (the polymerisation of the coating is activated by an electron beam) as well as UV (the polymerisation of the coating is activated by ultraviolet light) coatings with matting agents.

An example for such finishes are the products of the company Schattdecor: even surfaces Smartfoil, three-dimensional concave surfaces Smartfoil Real and three-dimensional convex surfaces Smartfoil Evo and Smartfoil 3D. Matting agents have a negative impact on the rheological properties of coating and complicate the coating process, especially by depositing on the applicator devices, e.g. paint rollers. The application of matting agents in coatings used for printing three-dimensional structures also limits the possibility to obtain structures with a highly diversified screen ruling due to the large size of the matting particles. In practice it is very difficult to achieve the chemical and mechanical standard for furniture foils with a gloss level of below 5° (when measured in a 60° geometry).

There is known means to obtain a gloss level of under 6° on the surface, which is to expose special types of UV or EB coatings to an excimer lamp emitting light with a wavelength of 172 nm.

One of the methods to produce a matte surface consists in applying a layer of EB coating on paper and treating it with an excimer lamp and then to harden it maximally with an electron beam (EB). This method, however, allows to obtain only one even, single-layer surface. No other layers can be applied to the hardened coating surface while ensuring the bond strength of these layers required in the furniture industry.

The aim of the invention is to develop a method for the production of multilayer, three-dimensional coated furniture surfaces, of which at least one coating layer is exposed to an excimer in order to mat it without using matting agents.

It was found that by exposing an applied layer of coating to light with a wavelength of 172 nm and by then gelatinising it by partial EB or UV hardening it was possible to repeat the application, excimer treatment and gelatinisation processes until complete hardening (complete polymerisation) of all coating layers. The obtained surface fulfils the requirements of the furniture industry concerning the resistance to delamination and to the influence of liquids as well as the mechanical resistance.

The essence of the invention is that the carrier is covered with layer of coating containing an additive increasing the bond strength of the coating between the layers. The coating is applied with a coating system. Then the applied coating layer is first exposed to excimer radiation with a wavelength of 172 nm and then to an electron beam with a dose of 2 to 7 kGy. This is the dose required to obtain the gelatinisation of the coating. The gelatinisation level is determined by means of an FTIR-test, where. with a wavelength of 1191 cm⁻¹, the transmittance value for the dose range of 3-5 kGy amounts from 45% to 50%, and the transmittance difference between two waves with lengths of about 2922 and 2878 cm⁻¹ amounts to about 5%, or where the transmittance value with a wavelength of about 1100 cm⁻¹ is lower compared to the transmittance for waves of about 1160 cm⁻¹. It is also possible to expose the coating to UV radiation in order to obtain an equivalent effect of gelatinisation. After this treatment, another layer of coating with a bond strength improving additive is then applied onto the first and also exposed to excimer radiation and to an electron beam, or to UV radiation, with the same dosage as for the first layer. If this second layer is the outer layer, i.e. the last layer, the whole surface is then exposed to an electron beam with a dose of minimum 35 kGy or to equivalent UV radiation in order to complete the polymerisation process of all coating layers. If the second layer is not the last layer, then the second layer is only exposed to excimer radiation and an electron beam or to UV radiation with the same dosage as for the first layer. The gelatinisation of the coating, i.e. its partial hardening, makes it possible to apply n layers of coating on the entire surface or a part of it. The transmittance value for the dose 40 kGy following complete polymerisation is over 60% with a wavelength of 1191 cm⁻¹, and the transmittance difference between two waves with lengths of about 2922 and 2878 cm⁻¹ amounts to about 10%, or the transmittance value with a wavelength of about 1100 cm⁻¹ is equal or higher compared to the transmittance for waves of about 1160 cm⁻¹. It is helpful when the additive improving the bond strength of the coating is selected from a group of additives on the basis of micronised wax based on very sensitive polyethylene with an addition of propoxylated glycerol triacrylate.

It is also advantageous to subject the coating to an electronic beam treatment with a dose of 2 to 6 kGy in order to ensure the bond strength between the layers.

The desired structure can be obtained on-line, during one passage through the coating machine or the printing and coating machine, or off-line, i.e. with several machines or in several passages through one machine, but the on-line method is better for the process.

The essence of the product containing a multilayer coated surface is that it contains at least one carrier covered with a multilayer matte coated surface obtained by one of the means described above, the surface being coated with at least one kind of coating containing an additive improving the bond strength, in the amount of 5 to 30% in weight, ensuring the bond strength between the layers. The three-dimensional effect of the furniture product is a resultant of the individual structures of the different layers.

It is of advantage, if the carrier material is paper or petroleum-based foil or chemical foil or a wood-based board.

It is also advantageous, if the carrier contains a printed layer.

It is also of advantage, if after hardening to a complete degree of polymerisation, the subsequent layers have a different gloss level.

The subject-matter of the invention is explained in execution examples.

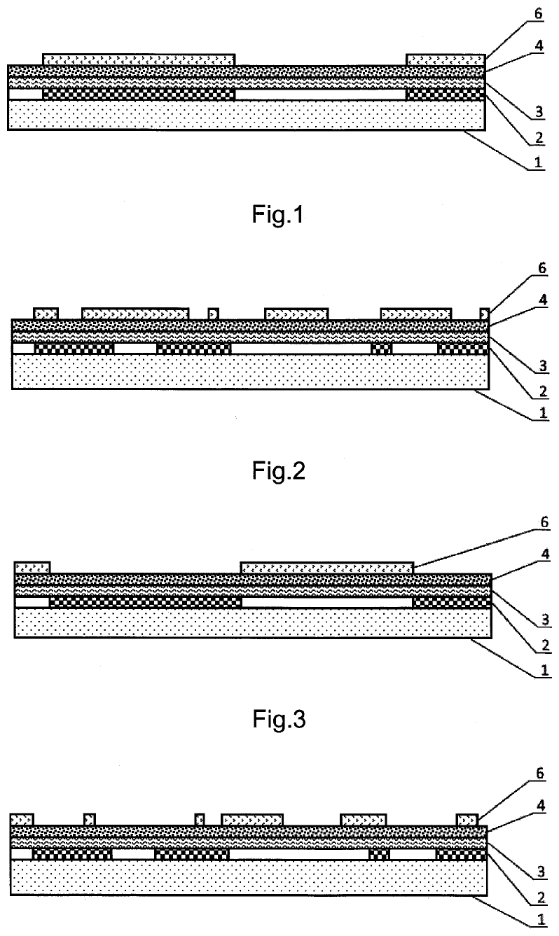

FIG. 1 shows a cross-section through a furniture foil with an effect obtained with a synchronous positive mould as described in example 1a, while

FIG. 2 shows the effect obtained with an asynchronous positive mould as described in example 1b.

FIG. 3 depicts a cross-section through a foil obtained with a negative mould with synchronous effect and

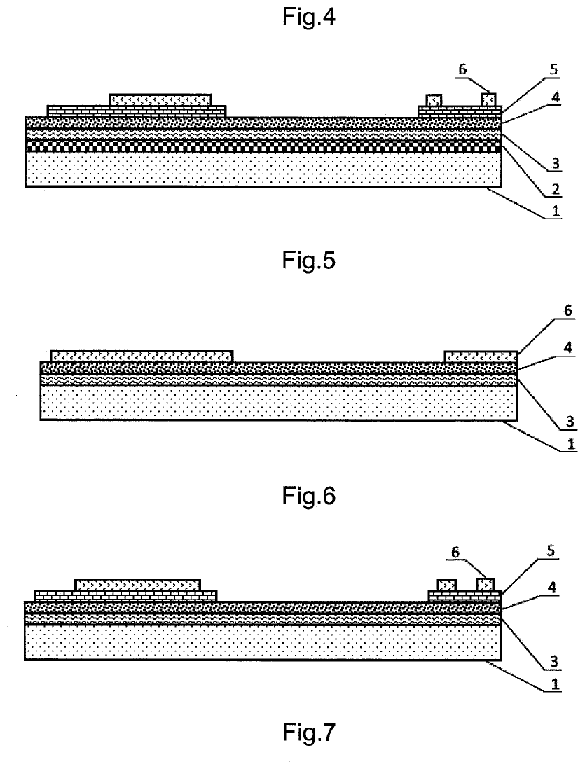

FIG. 4 shows the same with an asynchronous effect.

FIG. 5 presents a cross-section through a multilayer foil with overprint on the carrier.

FIG. 6 presents a cross-section through a furniture foil obtained with a positive mould, with two layers of coating with a colour effect provided by unprinted paper, while

FIG. 7 shows a cross-section through such a foil with three layers of coating.

### EXAMPLE 1A—POSITIVE MOULD, SYNCHRONOUS EFFECT

The foil production process is based on rotary intaglio printing. A wood-like design pattern 2 is applied onto carrier 1 which is made of paper foil. The design is transferred onto the band by pressing it with a special roller coated with rubber of adequate hardness to the printing cylinder. The cylinder is immersed in a rotating toner container with a feed roller. Excess paint is removed by means of an adjustable scraper blade on the printing cylinder. The band with the paint is then dried in a hot air chamber and afterwards transported to the next printing unit. The carrier passes through three printing stations. This process is performed with the use of water-soluble paints.

The next stage is to coat the carrier 1 with a protective layer 3. This is achieved by means of a special intaglio cylinder for the application of the primer 3717.212. The cylinder applies about 6 g/m² of the primer which, like the paint, is hardened in a gas dryer at a temperature of 140° C.

The next step is to apply the first layer of EB coating 4 by means of a 3WS coating system. At this stage of the process, the coat A has the following composition:
FL 27692—1 part
FLE 27800—0.1 parts
FZ 2711—0.07 parts
FZ 2720—0.15 parts

The obtained coating with a grammage of 8 g/m² is exposed to an excimer lamp and then a preliminary polymerisation process (gelatinisation) in an EB generator of the company PCT. The generator parameter settings are as follows:
Dose 5 kGy
High voltage 100 kV

The obtained surface has a gloss level below 6° measured in a 60° geometry. Then the carrier band is transported to a station with an intaglio cylinder with a synchronous pattern for the different elements of the main design. The structure 6 is imprinted using coating B composed of:
FLE 27800—1 part
FZ2720—0.15 parts

The surface is exposed to an excimer lamp and then hardened by means of electrons in an EB generator over the entire thickness of all coating layers. The hardening parameter values are:
Dose 40 kGy
High voltage 110 kV

The obtained foil, a cross-section of which is presented in FIG. 1, offers, apart from the visual effect of the imprinted design, also a haptic impression. The “porous” structure correlating with the different elements of the main design has a gloss level of 1-2° measured in a 60° geometry.

The content of the coating mixture in both application units is characterised by a special additive improving the bond strength between the individual layers. An additional condition for achieving good bond strength is that the coatings are subjected to a preliminary polymerisation (gelatinisation) of the coating layer at the stage of the production of the first matte surface coating.

### EXAMPLE 1B—POSITIVE MOULD, ASYNCHRONOUS EFFECT

The design and a protective layer are applied onto carrier 1 consisting of paper foil in the same manner as presented in example 1a.

The next step is to apply the first layer of EB coating 4 by means of a 3WS coating system. In this part of the process, the coat A has the following composition:
FL 27692—1 part
FLE 27800—0.1 parts
FZ 2711—0.07 parts
FZ 2720—0.15 parts

The obtained coating with a grammage of 8 g/m² is exposed to an excimer lamp and then a preliminary polymerisation process (gelatinisation) in an EB generator of the company PCT. The generator parameter settings are as follows:
Dose 5 kGy
High voltage 100 kV

The obtained surface has a gloss level below 6° measured in a 60° geometry. Then the carrier band is transported to a station with an intaglio cylinder with an asynchronous pattern for the different elements of the main design. The structure 6 is imprinted using coating B composed of:
FLE 27800—1.0 parts
FZ 2720—0.15 parts

The surface is exposed to an excimer lamp and then hardened by means of electrons in an EB generator over the entire thickness of all coating layers. The hardening parameter values are:
Dose 40 kGy
High voltage 110 kV

The obtained foil, a cross-section of which is presented in FIG. 2, offers, apart from the visual effect of the imprinted design, also a haptic impression. The “porous” structure not correlating with the different elements of the main design has a gloss level of 1-2° measured in a 60° geometry.

The content of the coating mixture in both application units is characterised by a special additive improving the bond strength between the individual layers. An additional condition for achieving good bond strength is that the coatings are subjected to a preliminary polymerisation (gelatinisation) of the coating layer at the stage of the production of the first matte surface coating.

### EXAMPLE 2A—NEGATIVE MOULD, SYNCHRONOUS EFFECT

The design 2 and the protective layer 3 are applied to carrier 1 consisting of paper foil in the same manner as presented in example 1a.

The next step is to apply the first layer of EB coating 4 by means of a 3WS coating system. In this part of the process, the coat A has the following composition:
FLE 27800—1.0 parts
FZ 2720—0.15 parts

The obtained coating with a grammage of 8 g/m² is exposed to an excimer lamp and then a preliminary polymerisation process (gelatinisation) in an EB generator of the company PCT. The generator parameter settings are as follows:
Dose 4 kGy
High voltage 100 kV

After this stage, a surface is obtained which is characterised by a gloss level of 1-2° measured in a 60° geometry and a gloss level of over 8° measured in a 85° geometry.

The next step in the production process is to apply the synchronous structure to the different elements of the main design.

The structure is imprinted using coating B 6 composed of:
FL 27692—1 part
FLE 27800—0.1 parts
FZ 2711—0.07 parts
FZ 2720—0.15 parts

The surface is exposed to an excimer lamp and then hardened by means of electrons in an EB generator over the entire thickness of all coating layers. The hardening parameter values are:
Dose 40 kGy
High voltage 110 kV

The layer of hardened coating applied with a negative intaglio cylinder has a gloss level of below 6° measured in a 60° geometry. The cross-section of this type of foil is shown in FIG. 3.

### EXAMPLE 2B—NEGATIVE MOULD, ASYNCHRONOUS EFFECT

The procedure is the same as in example 2a, with the following generator parameter settings for the preliminary polymerisation (gelatinisation):
Dose 5 kGy
High voltage 100 kV

After this stage, a surface is obtained which is characterised by a gloss level of 1-2° measured in a 60° geometry and a gloss level of over 8° measured in a 85° geometry.

The next step in the production process is to apply the asynchronous structure 6 to the different elements of the main design.

The structure is applied using coating B 6 with the same composition as in example 2a. The next steps are also the same as in example 2a. The gloss parameters of the resulting product are similar as in example 2a. The cross-section of this type of foil is shown in FIG. 4.

### EXAMPLE 3—N COATING LAVERS

The procedure is the same as in example 1 a, with the following generator parameter settings for the preliminary polymerisation (gelatinisation):
Dose 3 kGy
High voltage 100 kV

The obtained surface has a gloss level of below 6° measured in a 60° geometry. Then the carrier band is transported to a station with an intaglio cylinder with a synchronous pattern for the different elements of the main design. The structure 5 is applied using coating C composed of:
FLE 27800—1.0 part
FL 27692—1.0 part
FZ2720—0.15 parts

The obtained structure with a grammage of 3 g/m² is exposed to an excimer lamp and then a preliminary polymerisation process (gelatinisation) in an EB generator of the company PCT. The generator parameter settings are as follows:
Dose 4 kGy
High voltage 100 kV

Then the carrier band is transported to the station with the intaglio cylinder. The structure 6 is imprinted using coating B composed of:
FLE 27800—1.0 part
FZ2720—0.15 parts

The surface is exposed to an excimer lamp and then hardened with electrons in an EB generator over the entire thickness of all the coating layers. The hardening parameter values are:
Dose 40 kGy
High voltage 110 kV

The result is a three-dimensional structure with a matte effect. The corresponding cross-section is shown in FIG. 5.

### EXAMPLE 4A—OFF-LINE PRINTING, ASYNCHRONOUS, POSITIVE MOULD

The design 2 and a protective layer 3 are applied onto carrier 1 consisting of paper foil in the same manner as presented in example 1a. In the following technological cycle, the first layer of EB coating 4 is applied in a coating machine by means of a 3WS coating system.

In this part of the process, the coat A has the following composition:
FL 27692—1 part
FLE 27800—0.1 part
FZ 2711—0.07 parts
FZ 2720—0.15 parts

The obtained coating with a grammage of 8 g/m² is exposed to an excimer lamp and then a preliminary polymerisation process (gelatinisation) in an EB generator of the company PCT. The generator parameter settings are as follows:
Dose 4 kGy
High voltage 100 kV

The obtained surface has a gloss level below 6° measured in a 60° geometry. Then the carrier band is transported to the station with an intaglio cylinder with a pattern 6 which is asynchronous with the different elements of the main design. The structure is imprinted using coating B 6 composed of:
FLE 27800—1.0 part
FZ2720—0.05 parts

The surface is exposed to an excimer lamp and then hardened by means of electrons in an EB generator over the entire thickness of all coating layers. The hardening parameter values are:
Dose 40 kGy
High voltage 110 kV

The obtained foil, a cross-section of which is presented in FIG. 2, offers, apart from the visual effect of the imprinted design, also a haptic impression. The “porous” structure not correlating with the different elements of the main design has a gloss level of 1-2° measured in a 60° geometry and of over 8° measured in a 85° geometry.

The content of the coating mixture in both application units is characterised by a special additive improving the bond strength between the individual layers. An additional condition for achieving good bond strength is that the coatings are subjected to a preliminary polymerisation (gelatinisation) of the coating layer at the stage of the production of the first matte surface coating.

### EXAMPLE 4B—OFF-LINE PRINTING, ASYNCHRONOUS NEGATIVE MOULD

The design 2 and the protective layer 3 are applied to carrier 1 consisting of paper foil in the same manner as presented in example 1a. In the following technological cycle, the first layer of EB coating 4 is applied in a coating machine by means of a 3WS coating system.

In this part of the process, the coat A has the following composition:
FLE 27800—1.0 part
FZ2720—0.1 parts

The obtained coating with a grammage of 8 g/m² is exposed to an excimer lamp and then a preliminary polymerisation process (gelatinisation) in an EB generator of the company PCT. The generator parameter settings are as follows:
Dose 4 kGy
High voltage 100 kV

The surface obtained after this stage has a gloss level of 1-2° measured in a 60° geometry and a gloss level of over 8° measured in an 85° geometry.

In the next off-line technological cycle, the asynchronous structure 6 is applied to the different elements of the wood-like design at another coating machine.

At this stage of the process the coat B 6 has the following composition:
FL 27692—1 part
FLE 27800—0.1 parts
FZ 2711—0.07 parts
FZ 2720—0.2 parts

The surface is exposed to an excimer lamp and then hardened with electrons in an EB generator over the entire thickness of all the coating layers. The hardening parameter values are:
Dose 40 kGy
High voltage 110 kV

The layer of hardened coating applied with an intaglio cylinder has a gloss level of below 6° measured in a 60° geometry. The cross-section of this type of foil is shown in FIG. 4.

### EXAMPLE 5A—OFF-LINE PRINTING, MANY LAVERS, ASYNCHRONOUS, POSITIVE MOULD

The procedure is the same as in example 4a with a coating A 4 of the following composition:
FL 27692—1.0 part
FLE 27800—0.1 part
FZ 2711—0.07 parts
FZ 2720—0.15 parts

The obtained coating with a grammage of 8 g/m² is exposed to an excimer lamp and then a preliminary polymerisation process (gelatinisation) in an EB generator of the company PCT. The generator parameter settings are as follows:
Dose 3 kGy
High voltage 100 kV

The obtained surface has a gloss level below 6° measured in a 60° geometry. Then the carrier band is transported to a station with an intaglio cylinder with an asynchronous pattern for the different elements of the main design. The structure 5 is applied using coating C composed of:
FLE 27800—1.0 part
FL 27692—1.0 part
FZ2720—0.15 parts

The obtained coating with a grammage of 3 g/m² is exposed to an excimer lamp and then a preliminary polymerisation process (gelatinisation) in an EB generator of the company PCT. The generator parameter settings are as follows:
Dose 4 kGy
High voltage 100 kV

Then the carrier band is transported to the station with the intaglio cylinder. The structure 6 is imprinted using coating B composed of:
FLE 27800—1.0 part
FZ2720—0.30 parts

The surface is exposed to an excimer lamp and then hardened by means of electrons in an EB generator over the entire thickness of all coating layers. The hardening parameter values are:
Dose 40 kGy
High voltage 110 kV

The last layer of coating has a gloss level of 1-2° measured in a 60° geometry. The result is a three-dimensional matte structure the cross-section of which can be seen in FIG. 5.

### EXAMPLE 6—TWO LAYERS WITHOUT PRINT ON THE CARRIER

A protective base coat 3 consisting of Primer 3717.212 is applied to the carrier 1 consisting of paper foil in the same manner as described in example 1a.

The next step is to apply the first layer of EB coating 4 by means of a 3WS coating system. At this stage of the process, the coat A has the following composition:
FL 27692—1.0 part
FLE 27800—0.1 parts
FZ 2711—0.07 parts
FZ 2720—0.15 parts

The obtained coating with a grammage of 8 g/m² is exposed to an excimer lamp and then a preliminary polymerisation process (gelatinisation) in an EB generator of the company PCT. The generator parameter settings are as follows:
Dose 5 kGy
High voltage 100 kV

The obtained surface has a gloss level below 6° measured in a 60° geometry. Then the carrier band is transported to the station with the intaglio cylinder. The structure is imprinted using coating B 6 composed of:
FLE 27800—1.0 part
FZ2720—0.15 parts

The surface is exposed to an excimer lamp and then hardened by means of electrons in an EB generator over the entire thickness of all coating layers. The hardening parameter values are:
Dose 40 kGy
High voltage 110 kV

The applied “porous” structure has a gloss level of 1-2° measured in a 60° geometry. Its cross-section is shown in FIG. 6.

### EXAMPLE 7—OFF-LINE COATING, THREE LAVERS WITHOUT PRINT ON THE CARRIER

A protective base coat 3 consisting of Primer 3717.212 is applied to the carrier 1 consisting of paper foil in the same manner as described in example 1 a.

The next step is to apply the first layer of EB coating 4 by means of a 3WS coating system. At this stage of the process, the coat A has the following composition:
FL 27692—1.0 part
FLE 27800—0.1 part
FZ 2711—0.07 parts
FZ 2720—0.15 parts

The obtained coating with a grammage of 10 g/m² is exposed to an excimer lamp and then a preliminary polymerisation process (gelatinisation) in an EB generator of the company PCT. The generator parameter settings are as follows:
Dose 3 kGy
High voltage 100 kV

The obtained surface has a gloss level below 6° measured in a 60° geometry. Then the carrier band is transported to the station with the intaglio cylinder. The structure 5 is applied using coating C composed of:
FLE 27800—1.0 part
FL 27692—1.0 part
FZ2720—0.15 parts

The obtained coating with a grammage of 3 g/m² is exposed to an excimer lamp and then a preliminary polymerisation process (gelatinisation) in an EB generator of the company PCT. The generator parameter settings are as follows:
Dose 4 kGy
High voltage 100 kV

In the next off-line technological cycle, the structure 6 is applied to the carrier band at the station with the intaglio cylinder.

The structure is imprinted using coating B 6 composed of:
FLE 27800—1.0 part
FZ2720—0.15 parts

The surface is exposed to an excimer lamp and then hardened by means of electrons in an EB generator over the entire thickness of all coating layers. The hardening parameter values are:
Dose 40 kGy
High voltage 110 kV

The last layer of coating has a gloss level of 1-2° measured in a 60° geometry. The result is a three-dimensional structure with a matte effect, the cross-section of which is shown in FIG. 7.

### EXAMPLE 8—BOPP FOIL, POSITIVE MOULD, SYNCHRONOUS EFFECT

The foil production process is based on rotary intaglio printing. The wood-like design pattern 2 is applied to the carrier 1 consisting of BOPP foil. The design is transferred onto the band by pressing it with a special roller coated with rubber of adequate hardness to the printing cylinder. The cylinder is immersed in a rotating toner container with a feed roller. Excess paint is removed by means of an adjustable scraper blade on the printing cylinder. The band with the paint is then dried by IR radiation and afterwards transported to the next printing unit. The carrier passes through three printing stations. This process is performed with the use of water-soluble paints.

The next step is to apply the first layer of EB coating 4 by means of a 3WS coating system. At this stage of the process, the coat A has the following composition:
FL 27692—1.0 part
FLE 27800—0.1 part
FZ 2711—0.07 parts
FZ 2720—0.15 parts

The obtained coating with a grammage of 10 g/m² is exposed to an excimer lamp and then a preliminary polymerisation process (gelatinisation) in an EB generator of the company PCT. The generator parameter settings are as follows:
Dose 4 kGy
High voltage 100 kV

The obtained surface has a gloss level below 6° measured in a 60° geometry. Then the carrier band is transported to a station with an intaglio cylinder with a synchronous pattern for the different elements of the main design. The structure is imprinted using coating B 6 composed of:
FLE 27800—1.0 part
FZ2720—0.15 parts

The surface is exposed to an excimer lamp and then hardened with electrons in an EB generator over the entire thickness of all the coating layers. The hardening parameter values are:
Dose 40 kGy
High voltage 110 kV

The obtained foil offers, apart from the visual effect of the imprinted design, also a three-dimensional impression. The “porous” structure correlating with the different elements of the main design has a gloss level of 1-2° measured in a 60° geometry. The content of the coating mixture in both application units is characterised by a special additive improving the bond strength between the individual layers. An additional condition for achieving good bond strength is that the coatings are subjected to a preliminary polymerisation (gelatinisation) of the coating layer at the stage of the production of the first matte surface coating.

### EXAMPLE 9—OFF-LINE PRINTING, PML COATING—ROTODECOR COATING MACHINE, POSITIVE MOULD, ASYNCHRONOUS EFFECT

The first layer of EB coating 4 is applied to the carrier 1 previously imprinted with the design 2 and treated with Primer 3717.212 3 as in example 1 a by means of a DKR coating system. At this stage of the process, the coat A has the following composition:
FL 27692—1.0 part
FLE 27800—0.1 part
FZ 2711—0.07 parts
FZ 2720—0.15 parts

The obtained coating with a grammage of 7 g/m² is exposed to an excimer lamp and then a preliminary polymerisation process (gelatinisation) in an EB generator of the company PCT. The generator parameter settings are as follows:
Dose 5 kGy
High voltage 100 kV

The obtained surface has a gloss level below 6° measured in a 60° geometry. The carrier band is then again placed on the unwinder of the coating machine equipped with only one unit with excimer device and EB. In the next cycle the band is transported to the station with a intaglio cylinder with a pattern asynchronous with the different elements of the main design. The structure is imprinted using coat B 6 composed of:
FLE 27800—1.0 part
FZ2720—0.15 parts

The surface is exposed to an excimer lamp and then hardened by means of electrons in an EB generator over the entire thickness of all coating layers. The hardening parameter values are:
Dose 40 kGy
High voltage 110 kV

The obtained foil offers, apart from the visual effect of the imprinted design, also a three-dimensional impression. The “porous” structure not correlating with the different elements of the main design has a gloss level of 1-2° measured in a 60° geometry.

The content of the coating mixture in both application units is characterised by a special additive improving the bond strength between the individual layers. An additional condition for achieving good bond strength is that the coatings are subjected to a preliminary polymerisation (gelatinisation) of the coating layer at the stage of the production of the first matte surface coating.

### EXAMPLE 10—OFF-LINE DIGITAL IMPRINT, POSITIVE MOULD, ASYNCHRONOUS EFFECT

The first layer of EB coating 4 is applied by means of a 3WS coating system to the carrier 1 previously imprinted with the design 2 by means of a Palis digital printer and treated with Primer 3717.212 3. At this stage of the process, the coat A has the following composition:
FL 27692—1.0 part
FLE 27800—0.1 parts
FZ 2711—0.07 parts
FZ 2720—0.15 parts

The obtained coating with a grammage of 8 g/m² is exposed to an excimer lamp and then a preliminary polymerisation process (gelatinisation) in an EB generator of the company PCT. The generator parameter settings are as follows:
Dose 5 kGy
High voltage 100 kV

The obtained surface has a gloss level below 6° measured in a 60° geometry. Then the carrier band is transported to a station with an intaglio cylinder with an asynchronous pattern for the different elements of the main design. The structure is imprinted using coating B 6 composed of:
FLE 27800—1.0 parts
FZ2720—0.15 parts

The surface is exposed to an excimer lamp and then hardened by means of electrons in an EB generator over the entire thickness of all coating layers. The hardening parameter values are:
Dose 40 kGy
High voltage 110 kV

The obtained foil offers, apart from the visual effect of the imprinted design, also a three-dimensional impression. The “porous” structure not correlating with the different elements of the main design has a gloss level of 1-2° measured in a 60° geometry.

The content of the coating mixture in both application units is characterised by a special additive improving the bond strength between the individual layers. An additional condition for achieving good bond strength is that the coatings are subjected to a preliminary polymerisation (gelatinisation) of the coating layer at the stage of the production of the first matte surface coating.

### LIST OF SYMBOLS

1. Carrier
2. imprinted layer
3. protective layer
4. first excimer coating layer A
5. next excimer coating layer C
6. last excimer coating layer B

1. A method for the production of a multilayer matte coated surface on a carrier, finished with machines for the application of EB or UV coating, characterised in that, the carrier (1) is covered with a layer of coating (4) containing an additive improving the bond strength of the coating between the layers by a coating application system, the applied coating layer is then exposed to excimer radiation with a wavelength of 172 nm, following which the coating is treated with an electron beam with a dose from 2 to 7 kGy, which corresponds to the dose required to achieve a state of gelatinisation of the coating, or with UV radiation in order to achieve an adequate gelatinisation effect, at least one other layer of coating with bond strength improving additive is applied to the first layer, which is again exposed to excimer radiation and an electron beam or UV radiation with the same dose as for the first layer, where, if the second layer is the outer laver, i.e. the last layer (6), the entire surface is treated with an electron beam with a dose of minimum 35 kGy in order to finish the polymerisation process of all coating layers, or is treated with appropriate UV radiation, in order to achieve an adequate hardening effect.

2. A method according to claim 1 characterised in that the additive improving the bond strength of the coating is selected from a group of additives developed on the bases of micronised waxes based on very sensitive polyethylene with the addition of propoxylated glycerol triacrylate.

3. A method according to claim 1 characterised in that the coating is treated with an electron beam with a dose from 2 to 6 kGy.

4. A furniture product containing a multilayer coated surface and a carrier characterised in that it contains at least a carrier (1) covered with a multilayer matte coated surface obtained by the method according to claim 1, coated with at least one kind of coating (4) containing an additive improving the bond strength, in the amount of 5 to 30% in weight, where the three-dimensional effect of the furniture product is a resultant of the individual structures of the different layers.

5. Product in accordance with claim 4 characterised in that the carrier (1) is paper or petroleum-based foil or chemical foil or a wood-based board.

6. Product in accordance with claim 4 characterised in that the carrier (1) contains an imprinted layer (2).

7. Product in accordance with claim 4 characterised in that the following layers (4, 6), after having hardened to a complete degree of polymerisation, have a different gloss level.
